(19) United States
(12) Patent Application Publication
(10) Pub. No.: US 2015/0225874 A1
(43) Pub. Date: Aug. 13, 2015

(54) METHOD FOR GROWING ZIRCONIUM NITRIDE CRYSTAL

(71) Applicant: Sung Moo Kim, Gumi (KR)

(72) Inventor: Sung Moo Kim, Gumi (KR)

(73) Assignee: SM Technology, Gumi (KR)

(21) Appl. No.: 14/422,562

(22) PCT Filed: Aug. 21, 2012
(86) PCT No.: PCT/KR2012/006632

§ 371 Date: Feb. 19, 2015

(51) Int. Cl. C30B 25/02; C30B 29/38

(52) U.S. Cl. CPC C30B 25/02; C30B 29/38

(57) ABSTRACT

According to the present invention, if a zirconium nitride lattice is grown by a method for growing zirconium nitride using a metal-organic vapor phase epitaxy method, the lattice binding efficiency of ZrN and GaN can enable a low cost preparation of an LED having high performance and it is very advantageous to grow a green LED by a direct band gap in the presence of Zr3N4. In addition, InZr3N4 can be substituted for In when growing a MQW in an LED, and thus it is very advantageous to prepare green and red LEDs. Further, a more satisfactory diffusion current can be obtained using ZrN or Zr3N4 as an epitaxial interlayer, and thus it is very advantageous in the application of a large LED chip and it is possible to prevent thermal expansion or cracks with respect to a silicon substrate.

### BACKGROUND OF THE INVENTION

1. Field of the Invention

The present invention relates to a method for growing zirconium nitride crystal and, more particularly, to a method for growing zirconium nitride crystal which grows zirconium nitride crystal on a substrate using an epitaxial method.

2. Related Art

Gallium nitride (GaN) is a basic material for manufacturing blue and green light-emitting diodes (LEDs). Mostly, GaN LEDs are made by a metal-organic vapor phase epitaxy (MOCVD) process. And previously, a c-plane sapphire substrate is mainly used for manufacturing LEDs based on GaN.

However, various substrates have been used for manufacturing GaN LEDs recently. For example, a bulk GaN substrate, a silicon substrate, etc. have been used. The reason of using such substrates is to manufacture high quality GaN LEDs with low cost. However, as a matter of fact, it is very hard to attain the object by using the bulk GaN substrate, the silicon substrate, etc.

Meanwhile, LEDs generating light of blue or green wavelength band is grown by GaN, and LEDs generating light of red wavelength band is grown by gallium arsenide (GaAs). As such, substrates using different materials should be used depending on the wavelength of light, and also deposition equipments and epitaxial methods are different from each other. Thus, there is a problem that usage efficiency of the substrates and equipments is decreased.

In addition, in case of manufacturing large chips, there is a problem that current spread is hardly achieved, particularly, in p-GaN and n-GaN. According to this, by making an alternating current (AC) LED as a multi-array LED mask, it is implemented that current is better transferred in each of the chips. However, such a method has a problem that emitting area is significantly smaller due to the mask surface, thus emitting efficiency is degraded. And the emitting is not attained when a device problem occurs in a portion that connects each p-n junction.

Accordingly, a material is required to prevent cracks on surfaces, which has similar thermal expansion coefficient such as sapphire and supports the growth of aluminum nitride (AlN) when growing on silicon. In addition, it is required to manufacture blue, green and red LEDs using one MOCVD apparatus for growing GaN and it is available to decrease space for the equipment. Further, a pattern mask of large area and small area is required, which is made of a material that is able to decrease contact resistance owing to good current spreading.

### SUMMARY OF THE INVENTION

The present invention provides a method for growing zirconium nitride on a substrate using a metal-organic vapor phase epitaxy method.

In an aspect, a method for growing zirconium nitride on a substrate using a metal-organic vapor phase epitaxy method includes method for growing zirconium nitride using a metal-organic vapor phase epitaxy method includes placing a silicon substrate on a susceptor of a metal-organic vapor phase epitaxy method; heating the susceptor; and growing zirconium nitride crystal on the silicon substrate by supplying Tetrakis zirconium (TEMAZr) and ammonia gas into a chamber.

A lattice orientation of the substrate may be “111”, the zirconium nitride may be ZrN grown on the substrate by heating at 1050° C. or higher, the zirconium nitride may be ZrₓN_{y} grown on the substrate by heating lower than 1050° C., the ZrₓN_{y} may be grown at a temperature range 850 to 950° C., the ZrₓN_{y} may be Zr₃N₄, and the method may further include growing InZr₃N₄ by supplying In as reaction gas.

If a zirconium nitride lattice is grown by a method for growing zirconium nitride using a metal-organic vapor phase epitaxy method, the lattice binding efficiency of ZrₓN_{y} and GaN enable a low cost preparation of LEDs having high performance and it is very advantageous to grow a green LED by a direct band gap in the presence of Zr₃N₄.

In addition, Zr₃N₄ can be substituted for indium gallium (InGa) and used as InZr₃N₄ when growing a MQW in an LED, and thus it is very advantageous to prepare green and red LEDs. Further, a more satisfactory diffusion current can be obtained using ZrN or Zr₃N₄ as an epitaxial interlayer, and thus it is very advantageous in the application of a large LED chip and it is available to prevent thermal expansion or cracks with respect to a silicon substrate.

### BRIEF DESCRIPTION OF THE DRAWINGS

FIG. 1 illustrates a metal-organic vapor phase epitaxy apparatus for evaporating zirconium nitride using a metal-organic vapor phase epitaxy method according to an embodiment of the present invention.

FIG. 2 is a sectional view illustrating a shower head of a metal-organic vapor phase epitaxy apparatus for proceeding with a metal-organic vapor phase epitaxy method according to an embodiment of the present invention.

FIG. 3 is a block diagram for describing a metal-organic vapor phase epitaxy method according to an embodiment of the present invention.

FIG. 4 illustrates graphs analyzed by X-ray diffraction apparatus on the ZrN films formed on the silicon substrate at reaction temperatures of 850° C., 950° C. and 1050° C. according to an embodiment of the present invention.

### DESCRIPTION OF EXEMPLARY EMBODIMENTS

Hereinafter, embodiments of a method for growing zirconium nitride using a metal-organic vapor phase epitaxy method will be described with reference to accompanying drawings. However, the present invention is not limited to the embodiments described below but may be implemented as various forms. The embodiments described below are just provided for completing disclosure of the present invention, and for perfectly notifying scope of the present invention to a person who has ordinary skills.

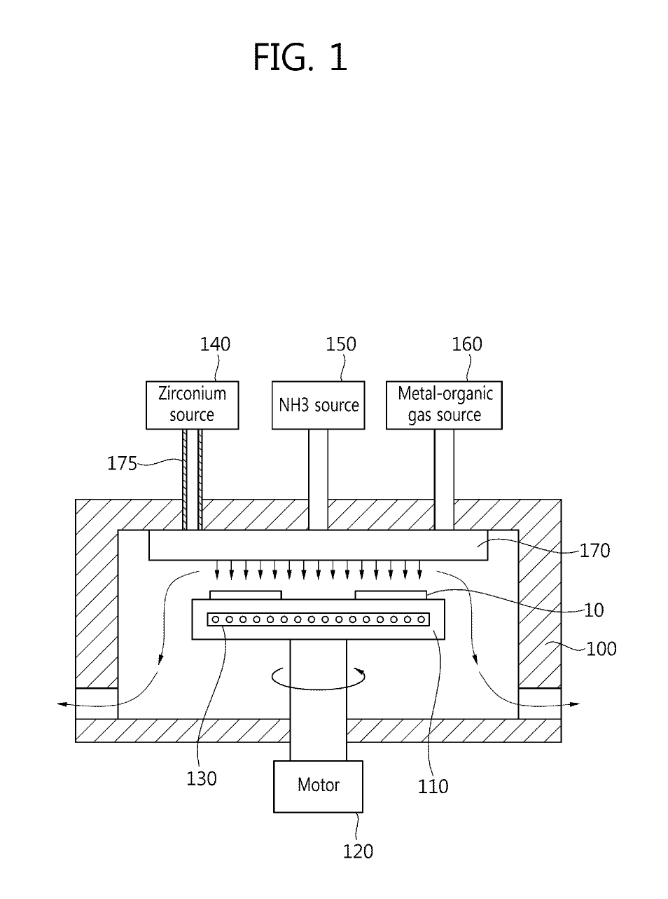

FIG. 1 illustrates a metal-organic vapor phase epitaxy apparatus for evaporating zirconium nitride using a metal-organic vapor phase epitaxy method according to an embodiment of the present invention.

As shown in FIG. 1, the evaporating apparatus includes a chamber 100. In upper portion of the chamber 100, a shower head 170 is provided. And a susceptor 110 is located under the shower head 170. In the susceptor 110, one or more substrates 10 are placed. The susceptor 110 is rotatable due to a motor 120 installed outside the chamber 100. In addition, in the susceptor 110 is installed a heater 130 for heating the substrate 10. The heater 130 may be implemented as a RF heater or a tungsten heater, and a plurality of heaters may be arranged and installed such that an individual heating control for several regions of the susceptor 110 is available.

And, outside the chamber 100, a zirconium source 140 for supplying zirconium gas, an NH₃ source 150 for supplying NH₃, and a metal-organic gas source 160 for supplying other metal-organic gases such as TMGa, TMAl, TMIn, 2-TMGa, 2-Cp2Mg, etc. are provided. In addition, although it is not depicted in the drawing, a gas source for supplying carrier gas, and nitrogen, argon or hydrogen gas for forming an atmosphere inside the chamber 100 may be separately provided.

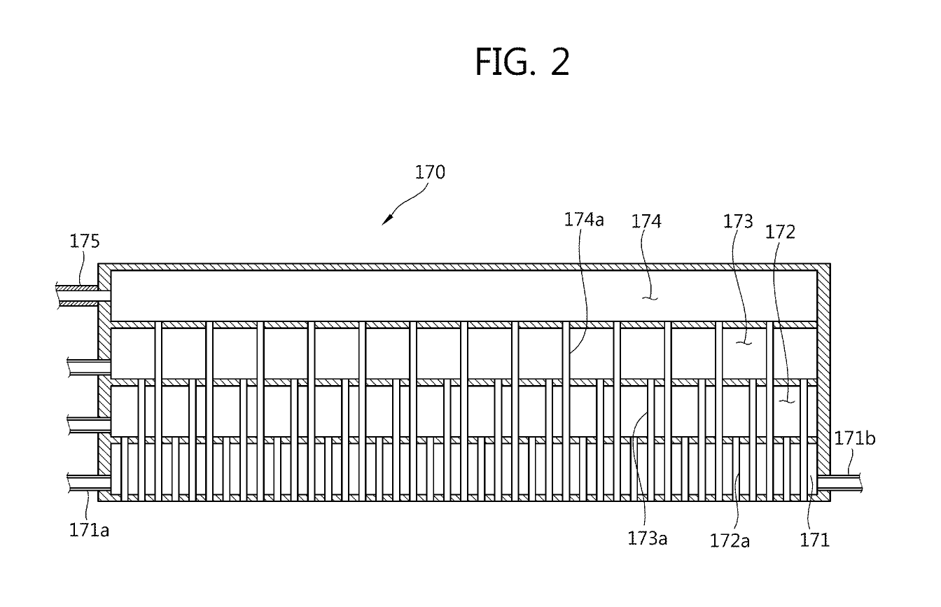

FIG. 2 is a sectional view illustrating a shower head of a metal-organic vapor phase epitaxy apparatus for proceeding with a metal-organic vapor phase epitaxy method according to an embodiment of the present invention.

As shown in FIG. 2, the shower head 170 is provided with a cooling layer 171 as the lowest layer. In the cooling layer 171 is formed an inlet 171a and an outlet 171b for circulating refrigerant like water.

On an upper portion of the cooling layer 171 is provided a first supply layer 172. NH₃ may be provided through the first supply layer 172. And first supply tubes 172a are installed through the cooling layer 171 from the first supply layer 172 in order to supply NH₃ gas into a processing space of the chamber 100. And on an upper portion of the first supply layer 172, a second supply layer 173 is provided. The metal-organic gases are supplied through the second supply layer 173, and second supply tubes 173a are installed sequentially penetrating the first supply layer 172 and the cooling layer 171 from the second supply layer 173.

And on an upper portion of the second supply layer 173, a third supply layer 174 is provided. Zirconium gas is supplied through the third supply layer 174, and third supply tubes 174a are provided in order to supply zirconium gas into the processing space of the chamber 100.

Meanwhile, a heating jacket 175 is provided for tubes and the third supply tubes 174a for supplying zirconium gas and, if required, for the third supply layer 174 in order to prevent evaporation on the tubes through which zirconium gas is supplied. The temperature of the heating jacket 175 may be maintained in the range of 50° C. to 90° C.

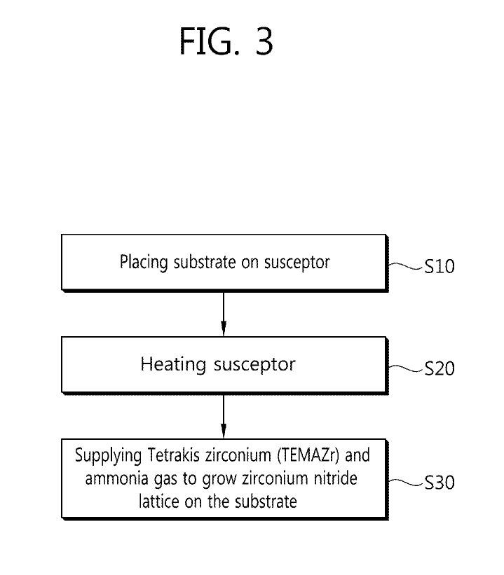

FIG. 3 is a block diagram for describing a metal-organic vapor phase epitaxy method according to an embodiment of the present invention.

As shown in FIG. 3, according to the metal-organic vapor phase epitaxy method according to an embodiment of the present invention, a substrate is placed on the susceptor 110 of the metal-organic vapor phase epitaxy apparatus (step, S10). And, the susceptor 110 is rotated and heated to a predefined temperature (step, S20). Later, zirconium nitride crystal is grown on a silicon substrate by supplying Tetrakis zirconium (TEMAZr) and ammonia gas inside the chamber 100 (step, S30).

Meanwhile, the characteristics of ZrN will be described in detail. ZrN (lattice orientation: 111) has a lattice mismatch smaller than aluminum nitride (AlN) for a GaN layer based on an LED (1.57% for ZrN and 2.5% for AlN). However, evaporating method for ZrN (111) is performed using ultrahigh-vacuum DC magnetron sputtering system conventionally, it is hard to evaporate pure ZrN (lattice orientation: 111) layer using the sputtering system. This is because a film only is evaporated but crystal growth is not properly attained in case of evaporating using the sputtering system.

However, if the ZrN (lattice orientation: 111) evaporation is performed using the metal-organic vapor phase epitaxy method, the crystal growth of ZrN is very effectively attained. Accordingly, the crystal growth is attained when proceeding with the metal-organic vapor phase epitaxy apparatus provided with the shower head 170 according to an embodiment of the present invention by placing the substrate 10 on the susceptor 110 inside the chamber 100.

If ZrN is evaporated on the silicon substrate 10 of which lattice orientation is “111”, the evaporation is effectively attained since ZrN grows on the same surface as NaCl structure. In case of evaporating ZrN on a sapphire substrate, the evaporation is more easily attained since the lattice mismatch is very small based on the surface of C-plane where GaN is grown.

In this time, n-type silicon substrate 10 may be used. In addition, since SiO₂ or other material may be evaporated with oxygen in air on the substrate 10, a substrate 10 may be used by being cleaned by de-ionization water and dried by ultra-pure nitrogen.

Metal-organic source Tetrakis (ethylmethylamino) zirconium (PEMAZr) and ammonia are used as the sources of zirconium (Zr) and nitrogen (N) in the embodiment of the present invention.

The reaction for forming ZrN using Tetrakis zirconium and ammonia are processed as Chemical formula 1.

[Chemical formula 1]

Zr[N(CH₃)(C₂H₅)]+NH₃(excess)→ZrN+2H[N(CH₃)(C₂H₅)]

Zr may be provided by being evaporated in a bowl which is controlled by the temperature over 60° C., and bubbled gas may be provided into the chamber 100. Zirconium provided from the zirconium source 140 is provided to the shower head 170 located at upper portion of the susceptor 110 while the zirconium is heated by the heating jacket 175 on the transfer tube.

And, N₂ or H₂ gas may be used as the carrier gas for the bubble of organic material from the bowl containing the source, or other inert gas such as Ar gas may be used. The pressure inside the chamber 100 may be implemented to about 5 torr, and the revolution speed may be implemented to 50 rpm/min.

ZrN lattice is grown on the silicon substrate 10 in a high temperature state. Hereinafter, an experimental example will be described for growing ZrN at three different temperatures, that is, 850° C., 950° C. and 1050° C., respectively, in the metal-organic vapor phase deposition apparatus.

First, for the ZrN growth at 850° C., a surface of the n-type silicon substrate 10 is cleaned by annealing in hydrogen gas atmosphere during 15 minutes at 1100° C. Later, after growing ZrN lattice on the silicon substrate 10 by heating at 850° C., 950° C. and 1050° C. in nitrogen gas atmosphere during 100 minutes, the inside of the chamber 100 may be cooled down for about 30 minutes. In this time, the flow rate of TEMAZr as the organic source and NH₃ which are provided may be 12.5 mol/min and 2 slm/min, respectively.

The ZrN crystal grown by the embodiment of the present invention is analyzed using X-ray diffraction apparatus (XRD spectra) by analyzing the surfaces of silicon substrates evaporated at 850° C., 950° C. and 1050° C., respectively.

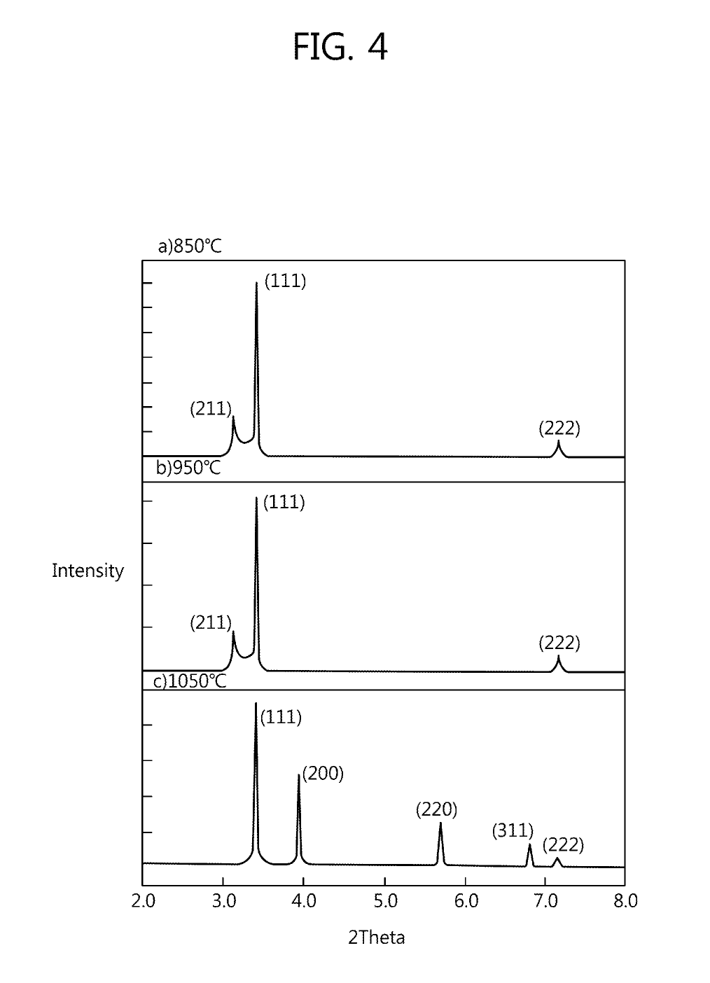

FIG. 4 illustrates graphs analyzed by X-ray diffraction apparatus on the ZrN films formed on the silicon substrate at reaction temperatures of 850° C., 950° C. and 1050° C. according to an embodiment of the present invention. The theta angle peaks of X-ray diffraction analysis shown in FIG. 4 are performed in the range of 20° to 80°. Accordingly, seen from the measurement results shown in FIG. 4, it can be noticed that the crystal structures of ZrN grown at 850° C., 950° C. and 1050° C. respectively are different.

According to this, it can be verified that ZrN crystal growth is attained on the silicon substrate 10 in case of proceeding with the process at the temperature of 1050° C. or higher. And it can be verified that growth of ZrₓN_{y} (for example, Zr₃N₄) is attained at the temperature of 1050° C. or lower. In case of reheating ZrₓN_{y} at 1050° C. or higher again after growing it at low temperature, the crystal structure may be changed to ZrN.

As described above, ZrN lattice grown on the silicon substrate 10 has good lattice binding efficiency with GaN in the LED manufacture, which enables a low cost preparation of LEDs having high performance and it is very advantageous to grow LEDs.

In addition, Zr₃N₄ is very advantageous to grow green LEDs having direct band gap. And Zr₃N₄ can be substituted for gallium (Ga) and used as InZr₃N₄ when growing a MQW in an LED, and in this case, it is very advantageous to manufacture green and red LEDs.

The reaction of forming InZrN layer using TMIn (trimethyl indium) is proceeding as Chemical formula 2 or Chemical formula 3.

[Chemical formula 2]

In(CH₃)₃+Zr(n(CH₃)(C₂H₅))₄+NH₃(excess)→InZrN+2H(N(CH₃)(C₂H₅))+CH₄

[Chemical formula 3]

XIn(CH₃)₃+(1−X)Zr(NMeEt)₄+NH₃(excess)→InZr_{(1-X)}N+3XCH₄+4(1−X)HN(Me)(Et)

Further, a more satisfactory diffusion current can be obtained using ZrN or Zr₃N₄ as an epitaxial interlayer, and thus it is very advantageous in the application of a large LED chip and it is also available to prevent thermal expansion or cracks with respect to a silicon substrate.

Such a reaction for Zr₃N₄ is proceeding as Chemical formula 4 or Chemical formula 5.

[Chemical formula 4]

In(CH3₃)₃+3Zr(n(CH₃)(C₂H₅))₄+4NH₃(excess)→InZr₃N₄+6H(N(CH₃)(C₂H₅))+CH ₄

[Chemical formula 5]

XIn(CH₃)₃+3(1−X)Zr(NMeEt)₄+NH₃(excess)→InZr₃(1−X)N₄+3XCH₄+4(1−X)HN(Me)(Et)

The embodiments of the present invention as described above should not be interpreted to limit the inventive concept of the present invention. The scope of the present invention is only limited by the claims, and a person skilled in the art is available to improve or alter the inventive concept of the present invention in various forms. Accordingly, the improvement and alteration, as far as obvious to the person skilled in the art, should be pertained in the scope of the present invention.

What is claimed is:

1. A method for growing zirconium nitride using a metal-organic vapor phase epitaxy method, the method comprising:
placing a silicon substrate on a susceptor of a metal-organic vapor phase epitaxy method;
heating the susceptor; and
growing zirconium nitride crystal on the silicon substrate by supplying Tetrakis zirconium (TEMAZr) and ammonia gas into a chamber.

2. The method for growing zirconium nitride using a metal-organic vapor phase epitaxy method of claim 1, wherein a lattice orientation of the substrate is “111”.

3. The method for growing zirconium nitride using a metal-organic vapor phase epitaxy method of claim 1, wherein the zirconium nitride is ZrN grown on the substrate by heating at 1050° C. or higher.

4. The method for growing zirconium nitride using a metal-organic vapor phase epitaxy method of claim 1, wherein the zirconium nitride is ZrₓN_{y} grown on the substrate by heating lower than 1050° C.

5. The method for growing zirconium nitride using a metal-organic vapor phase epitaxy method of claim 4, wherein the ZrₓN_{y} is grown at a temperature range 850 to 950° C.

6. The method for growing zirconium nitride using a metal-organic vapor phase epitaxy method of claim 5, wherein the ZrₓN_{y} is Zr₃N₄.

7. The method for growing zirconium nitride using a metal-organic vapor phase epitaxy method of claim 1 further comprising growing InZr₃N₄ by supplying In as reaction gas.
